(19) United States
(12) Patent Application Publication
(10) Pub. No.: US 2025/0149507 A1
(43) Pub. Date: May 8, 2025

(54) SEMICONDUCTOR PACKAGE INCLUDING ENCAPSULATION LAYERS

(71) Applicant: SK hynix Inc., Icheon-si Gyeonggi-do (KR)

(72) Inventor: Jae Min KIM, Icheon-si Gyeonggi-do (KR)

(73) Assignee: SK hynix Inc., Icheon-si Gyeonggi-do (KR)

(21) Appl. No.: 18/444,183

(22) Filed: Feb. 16, 2024

(30) Foreign Application Priority Data
Nov. 8, 2023 (KR) 10-2023-0153511

(51) Int. Cl. H01L 25/065; H01L 23/00; H01L 23/29; H01L 23/31

(52) U.S. Cl. CPC H01L 25/0657; H01L 23/293; H01L 23/3135; H01L 24/13; H01L 24/16; H01L 24/48; H01L 24/32; H01L 24/73; H01L 2224/13147; H01L 2224/16227; H01L 2224/32145; H01L 2224/48227; H01L 2224/73253; H01L 2224/73265; H01L 2225/06562

(57) ABSTRACT

A semiconductor package includes a bonding wire which is connected to a semiconductor chip. A first encapsulation layer which surrounds the bonding wire is disposed. A second encapsulation layer which surrounds the first encapsulation layer is disposed. A surface roughness of the first encapsulation layer is less than that of the second encapsulation layer. A landing pad which contacts the bonding wire is disposed.

### CROSS-REFERENCE TO RELATED APPLICATION

The present application claims priority under 35 U.S.C. § 119 (a) to Korean Patent Application No. 10-2023-0153511 filed in the Korean Intellectual Property Office on Nov. 8, 2023, which is incorporated herein by reference in its entirety.

### BACKGROUND

### 1. Technical Field

Various embodiments generally relate to a semiconductor package, and more particularly, to a semiconductor package including encapsulation layers and a method for forming the semiconductor package including the encapsulation layers.

### 2. Related Art

In response to the demand for highly integrated semiconductor devices, technology for stacking semiconductor chips is being attempted. The semiconductor chips include input/output interconnections. Technology for forming a redistribution layer, connected to the input/output interconnections, on a chip stack including the semiconductor chips faces various technical limitations.

### SUMMARY

In an embodiment, a semiconductor package may include a bonding wire which is connected to a semiconductor chip. A first encapsulation layer which surrounds the bonding wire may be disposed. A second encapsulation layer which surrounds the first encapsulation layer may be disposed. A surface roughness of the first encapsulation layer may be smaller than that of the second encapsulation layer. A landing pad which contacts the bonding wire may be disposed.

In an embodiment, a semiconductor package may include a connecting interconnection which is connected to a semiconductor chip. A first encapsulation layer which surrounds the connecting interconnection may be disposed. A second encapsulation layer which surrounds the first encapsulation layer may be disposed. A surface roughness of the first encapsulation layer may be smaller than that of the second encapsulation layer. A landing pad which contacts the connecting interconnection may be disposed. The connecting interconnection may include a vertical wire, a conductive pillar, a conductive bump or a combination thereof.

In an embodiment, a semiconductor package may include a chip stack including a plurality of semiconductor chips which are stacked to be offset from each other. A copper pillar bump which is connected to one semiconductor chip disposed at an uppermost layer among the plurality of semiconductor chips may be provided. A plurality of vertical wires which are connected to remaining semiconductor chips except the one semiconductor chip disposed at the uppermost layer among the plurality of semiconductor chips may be provided. A first encapsulation layer which is adjacent to the plurality of vertical wires and the copper pillar bump may be disposed. A second encapsulation layer may be disposed outside the first encapsulation layer. A surface roughness of the first encapsulation layer may be smaller than that of the second encapsulation layer. A plurality of landing pads may be disposed on the plurality of vertical wires and the copper pillar bump.

### BRIEF DESCRIPTION OF THE DRAWINGS

FIG. 1 is a cross-sectional view for explaining a semiconductor package based on an embodiment of the disclosed technology.

FIGS. 2 and 3 are partial views illustrating an embodiment of a part of FIG. 1.

FIG. 4 is a layout diagram for explaining the semiconductor package based on an embodiment of the disclosed technology.

FIG. 5 is a cross-sectional view for explaining a semiconductor package based on an embodiment of the disclosed technology.

FIGS. 6 to 14 are cross-sectional views for explaining methods for forming a semiconductor package based on embodiments of the disclosed technology.

### DETAILED DESCRIPTION

Various embodiments of the disclosed technology are directed to providing a semiconductor package which prevents or mitigates a reliability defect and is advantageous for high integration, and a method for forming the semiconductor package.

According to various embodiments of the disclosed technology, it is possible to implement a semiconductor package which prevents or mitigates a reliability defect and is, thus, advantageous for high integration.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

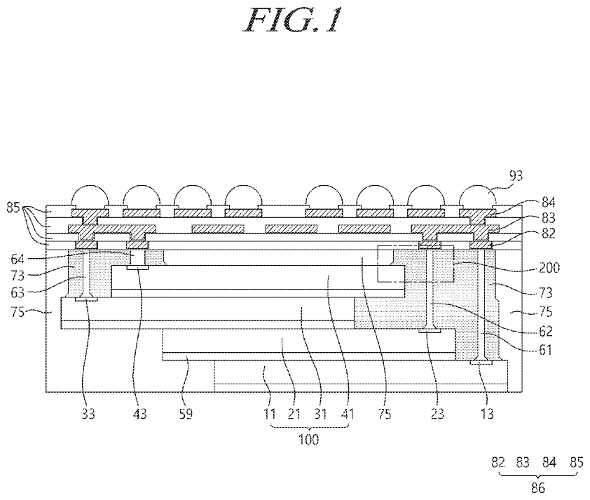

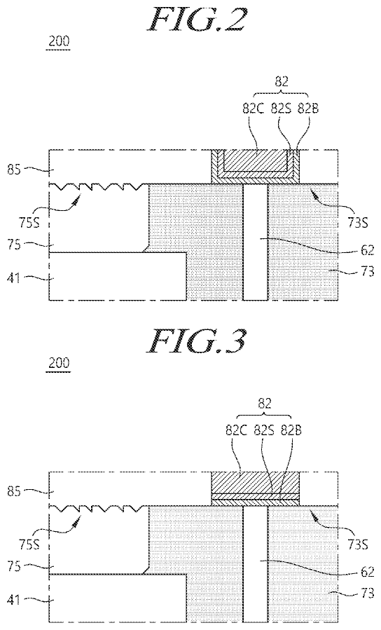

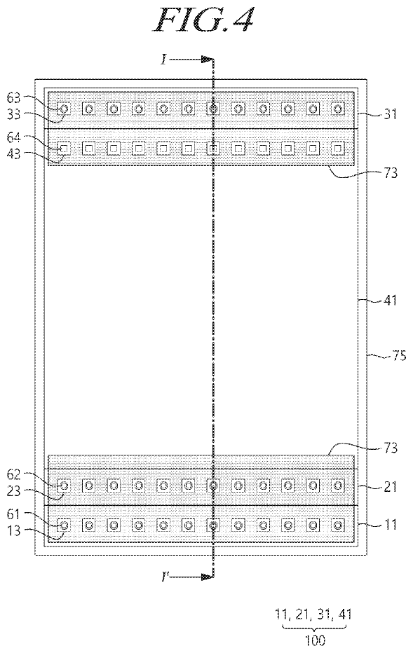

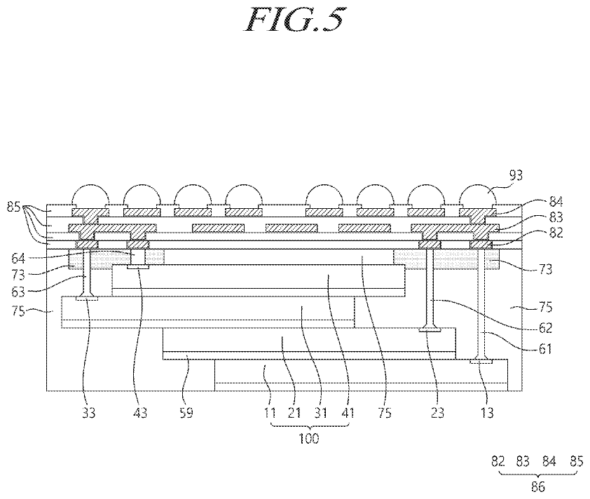

FIG. 1 is a cross-sectional view for explaining a semiconductor package based on an embodiment of the disclosed technology, and FIGS. 2 and 3 are partial views illustrating an embodiment of a part 200 of FIG. 1. FIG. 4 is a layout diagram for explaining the semiconductor package based on an embodiment of the disclosed technology. FIG. 1 may be a cross-sectional view taken along the lines I-I′ of FIG. 4.

Referring to FIGS. 1 and 4, the semiconductor package based on the embodiment of the disclosed technology may include a chip stack 100, connecting interconnections 61, 62, 63 and 64, a first encapsulation layer 73, a second encapsulation layer 75, a redistribution layer 86, and external connection terminals 93. The redistribution layer 86 may include landing pads 82, internal interconnections 83, top pads 84, and an insulating layer 85.

The chip stack 100 may include semiconductor chips 11, 21, 31 and 41. In an embodiment, the semiconductor chips 11, 21, 31 and 41 may include a first semiconductor chip 11, a second semiconductor chip 21, a third semiconductor chip 31, and a fourth semiconductor chip 41. The second semiconductor chip 21 may be stacked on the first semiconductor chip 11 to be offset in a first direction, the third semiconductor chip 31 may be stacked on the second semiconductor chip 21 to be offset in the first direction, and the fourth semiconductor chip 41 may be stacked on the third semiconductor chip 31 to be offset in a second direction different from the first direction. The second direction may be opposite to the first direction. For example, the first direction may be a left direction and the second direction may be a right direction as, for example, shown in FIG. 1. Adhesive layers 59 may be formed between the semiconductor chips 11, 21, 31 and 41. The first semiconductor chip 11 may be disposed at the lowermost end of the chip stack 100, and the fourth semiconductor chip 41 may be disposed at the uppermost end of the chip stack 100.

The semiconductor chips 11, 21, 31 and 41 may include chip terminals 13, 23, 33 and 43, respectively. The chip terminals 13, 23, 33 and 43 may include first chip terminals 13 of the first semiconductor chip 11, second chip terminals 23 of the second semiconductor chip 21, third chip terminals 33 of the third semiconductor chip 31, and fourth chip terminals 43 of the fourth semiconductor chip 41. Each ones of the chip terminals 13, 23, 33 and 43 may be disposed in various ways on one surface of a corresponding one among the semiconductor chips 11, 21, 31 and 41. In an embodiment, each ones of the chip terminals 13, 23, 33 and 43 may be aligned at regular intervals adjacent to an edge of a corresponding one among the semiconductor chips 11, 21, 31 and 41. The respective semiconductor chips 11, 21, 31 and 41 may be arranged in a staggered manner in such a way to not overlap but expose the chip terminals 13, 23, 33 and 43 of other semiconductor chips 11, 21, 31 and 41.

The connecting interconnections 61, 62, 63 and 64 may be disposed on the chip terminals 13, 23, 33 and 43. The connecting interconnections 61, 62, 63 and 64 may include first connecting interconnections 61 on the first chip terminals 13, second connecting interconnections 62 on the second chip terminals 23, third connecting interconnections 63 on the third chip terminals 33, and fourth connecting interconnections 64 on fourth chip terminals 43.

Each of the connecting interconnections 61, 62, 63 and 64 may extend in a vertical direction from one surface of a corresponding one of the semiconductor chips 11, 21, 31 and 41. In an embodiment, each of the connecting interconnections 61, 62, 63 and 64 may extend in the vertical direction on each of the chip terminals 13, 23, 33 and 43. The uppermost end of each of the connecting interconnections 61, 62, 63 and 64 may extend to a level higher than the top surface of an uppermost semiconductor chip (e.g., the fourth semiconductor chip 41). Each of the connecting interconnections 61, 62, 63 and 64 may include a vertical wire, a conductive pillar, a conductive bump or a combination thereof. In an embodiment, the connecting interconnections 61, 62, 63 and 64 may include bonding wires.

In an embodiment, the connecting interconnection of an uppermost semiconductor chip may be a conductive bump, and the connecting interconnections of remaining semiconductor chips except the uppermost semiconductor chip may be bonding wires. For example, the first to third connecting interconnections 61, 62 and 63 of the first semiconductor chip 11, the second semiconductor chip 21 and the third semiconductor chip 31 may be bonding wires, and the fourth connecting interconnections 64 of the fourth semiconductor chip 41 may be conductive bumps.

The first encapsulation layer 73 may be disposed adjacent to the connecting interconnections 61, 62, 63 and 64 on the chip stack 100. The first encapsulation layer 73 may cover partial regions of the chip stack 100 adjacent to the connecting interconnections 61, 62, 63 and 64. The first encapsulation layer 73 may be formed to surround the side surfaces of the connecting interconnections 61, 62, 63 and 64. The first encapsulation layer 73 may directly contact the side surfaces of the connecting interconnections 61, 62, 63 and 64. The first encapsulation layer 73 may contact the top surfaces of the semiconductor chips 11, 21, 31 and 41. In an embodiment, the bottom surface of the first encapsulation layer 73 may directly contact the top surface of the first semiconductor chip 11. The lowermost end of the first encapsulation layer 73 may be formed at a level equal to or higher than the top surface of the first semiconductor chip 11. The uppermost end of the first encapsulation layer 73 may be formed at a level higher than the top surface of the fourth semiconductor chip 41.

The connecting interconnections 61, 62, 63 and 64 may be connected to the chip terminals 13, 23, 33 and 43 by passing through the first encapsulation layer 73 in the vertical direction as, for example, shown in FIG. 1. The lower ends of the connecting interconnections 61, 62, 63 and 64 may directly contact the chip terminals 13, 23, 33 and 43. The connecting interconnections 61, 62, 63 and 64 may be connected to the internal circuits of the semiconductor chips 11, 21, 31 and 41 through the chip terminals 13, 23, 33 and 43.

The second encapsulation layer 75 may cover the surface of the first encapsulation layer 73 and cover the side surface and the top surface of the chip stack 100. The top surface of the fourth semiconductor chip 41 may be covered with the second encapsulation layer 75 and the first encapsulation layer 73. The top surfaces of the second encapsulation layer 75, the first encapsulation layer 73 and the connecting interconnections 61, 62, 63 and 64 may form substantially the same plane. In an embodiment, the second encapsulation layer 75 may be formed to surround the side surface of the first encapsulation layer 73.

The redistribution layer 86 may be disposed on the second encapsulation layer 75, the first encapsulation layer 73 and the connecting interconnections 61, 62, 63 and 64. The landing pads 82, the internal interconnections 83 and the top pads 84 may be disposed in the insulating layer 85. The landing pads 82 may directly contact the connecting interconnections 61, 62, 63 and 64 and extend onto the first encapsulation layer 73. The bottom surfaces of the landing pads 82 may directly contact the top surface of the first encapsulation layer 73. The bottom surface of the insulating layer 85 may directly contact the top surface of the second encapsulation layer 75 and the top surface of the first encapsulation layer 73. The landing pads 82, the connecting interconnections 61, 62, 63 and 64 and the chip terminals 13, 23, 33 and 43 may overlap each other in the vertical direction as, for example, shown in FIG. 1. In an embodiment, a plurality of landing pads 82 may be disposed in the insulating layer 85. Each of the plurality of landing pads 82 may overlap a corresponding one among the connecting interconnections 61, 62, 63 and 64 in the vertical direction. Each of the connecting interconnections 61, 62, 63 and 64 may overlap a corresponding one among the chip terminals 13, 23, 33 and 43 in the vertical direction.

The top pads 84 may be electrically connected to the landing pads 82 through the internal interconnections 83. The external connection terminals 93 may be disposed on the top pads 84. The external connection terminals 93 may be electrically connected to the internal circuits of the semiconductor chips 11, 21, 31 and 41 through the top pads 84, the internal interconnections 83, the landing pads 82, the connecting interconnections 61, 62, 63 and 64 and the chip terminals 13, 23, 33 and 43.

Referring to FIG. 2, the first encapsulation layer 73 may include a first surface 73S. The second encapsulation layer 75 may include a second surface 75S. The landing pad 82 may include a barrier layer 82B, a seed layer 82S and a conductive layer 82C. In an embodiment, the barrier layer 82B may be formed to surround the side surfaces and the bottom surface of the conductive layer 82C. The seed layer 82S may be disposed between the barrier layer 82B and the conductive layer 82C. Each of the top pads 84 and the internal interconnections 83 may include a configuration similar to the landing pad 82. The first surface 73S of the first encapsulation layer 73, the second surface 75S of the second encapsulation layer 75 and one surface of the second connecting interconnection 62 may form substantially the same plane.

The first surface 73S of the first encapsulation layer 73 and the second surface 75S of the second encapsulation layer 75 may have different surface roughnesses. The first surface 73S may have a first roughness, and the second surface 75S may have a second roughness. Due to the material composition of each of the first encapsulation layer 73 and the second encapsulation layer 75, the first roughness may be less than the second roughness.

In an embodiment, the first encapsulation layer 73 may include first resin and first fillers. The second encapsulation layer 75 may include second resin and second fillers. The average size of the first fillers may be smaller than the average size of the second fillers. In an embodiment, the first fillers of the first encapsulation layer 73 may have a size equal to or smaller than 3 micrometers. In an embodiment, the first fillers of the first encapsulation layer 73 may have a size of 0.1 micrometer to 3 micrometers. In an embodiment, the second fillers of the second encapsulation layer 75 may have a size equal to or smaller than 30 micrometers. In an embodiment, the second fillers of the second encapsulation layer 75 may have a size of 0.1 micrometer to 30 micrometers. In an embodiment, the average size of the first fillers of the first encapsulation layer 73 may be 1 micrometer to 2 micrometers. In an embodiment, the average size of the second fillers of the second encapsulation layer 75 may be 10 micrometers to 20 micrometers.

In an embodiment, the volume ratio of the first fillers in the first encapsulation layer 73 may be smaller than the volume ratio of the second fillers in the second encapsulation layer 75. In an embodiment, the volume ratio of the first fillers in the first encapsulation layer 73 may be 30% to 60%. In an embodiment, the volume ratio of the second fillers in the second encapsulation layer 75 may be 70% to 90%. In an embodiment, the volume ratio of the first fillers in the first encapsulation layer 73 may be about 50%, and the volume ratio of the second fillers in the second encapsulation layer 75 may be about 80%.

The bottom surface of the landing pad 82 may directly contact the top surface of the second connecting interconnection 62, and may extend onto the first surface 73S of the first encapsulation layer 73. The bottom surface of the landing pad 82 may directly contact the first surface 73S of the first encapsulation layer 73 adjacent to the second connecting interconnection 62. The bottom surface of the insulating layer 85 may directly contact the second surface 75S of the second encapsulation layer 75 and the first surface 73S of the first encapsulation layer 73.

A process of forming the barrier layer 82B and the seed layer 82S may include a physical vapor deposition (PVD) method, a chemical vapor deposition (CVD) method or a combination thereof. The first surface 73S which has a relatively small surface roughness may be advantageous for forming a uniform thin film while minimizing the thicknesses of the barrier layer 82B and the seed layer 82S. A process of forming the conductive layer 82C may include an electroplating method.

According to an embodiment of the technical spirit of the disclosed technology, due to the presence of the first surface 73S of the first encapsulation layer 73 which has a relatively small surface roughness, it is possible to prevent or mitigate a defect such as a pin hole from occurring in the barrier layer 82B and the seed layer 82S. In an embodiment, tt is possible to prevent or mitigate a reliability defect such as copper (Cu) cloud from occurring in the landing pad 82. In an embodiment, due to the presence of the second surface 75S of the second encapsulation layer 75 which has a relatively large surface roughness, the bonding strength of the insulating layer 85 and the second encapsulation layer 75 may be increased. In an embodiment, it is possible to prevent or mitigate a defect such as delamination from occurring between the insulating layer 85 and the second encapsulation layer 75.

Referring to FIG. 3, a seed layer 82S may be disposed on a barrier layer 82B, and a conductive layer 82C may be disposed on the seed layer 82S. The barrier layer 82B may directly contact the top surface of the second connecting interconnection 62 and the first surface 73S of the first encapsulation layer 73.

FIG. 5 is a cross-sectional view for explaining a semiconductor package based on an embodiment of the disclosed technology.

Referring to FIG. 5, the lowermost end of the first encapsulation layer 73 may be disposed at a level higher than the bottom surface of an uppermost semiconductor chip (e.g., the fourth semiconductor chip 41). The lowermost end of the first encapsulation layer 73 may be disposed at a level lower than the top surface of the fourth semiconductor chip 41 as, for example, shown in FIG. 5.

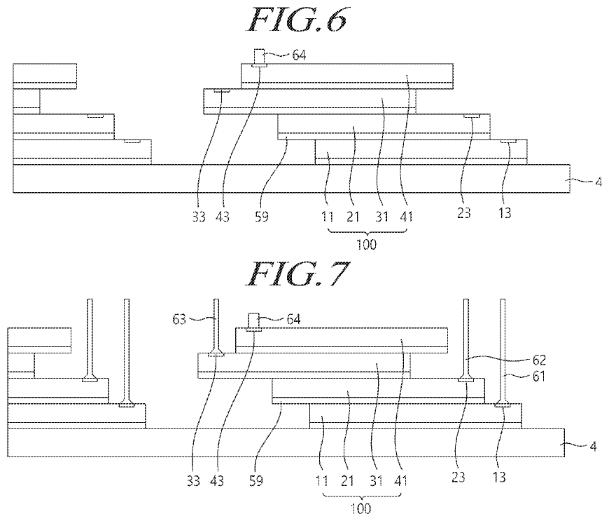

FIGS. 6 to 11 are cross-sectional views for explaining a method for forming a semiconductor package based on an embodiment of the disclosed technology.

Referring to FIG. 6, the method for forming a semiconductor package based on the embodiment of the disclosed technology may include forming chip stacks 100 on a carrier 4. The respective chip stacks 100 may be disposed to be spaced apart from each other.

Each of the chip stacks 100 may include semiconductor chips 11, 21, 31 and 41. In an embodiment, the semiconductor chips 11, 21, 31 and 41 may include a first semiconductor chip 11, a second semiconductor chip 21, a third semiconductor chip 31, and a fourth semiconductor chip 41. The first semiconductor chip 11 may be stacked on the carrier 4. The second semiconductor chip 21 may be stacked on the first semiconductor chip 11 to be offset in the first direction. The third semiconductor chip 31 may be stacked on the second semiconductor chip 21 to be offset in the first direction. The fourth semiconductor chip 41 may be stacked on the third semiconductor chip 31 to be offset in the second direction. The second direction may be opposite to the first direction. For example, the first direction may be a left direction and the second direction may be a right direction as, for example, shown in FIG. 6. Adhesive layers 59 may be formed between the first semiconductor chip 11 and the carrier 4 and between the semiconductor chips 11, 21, 31 and 41. In an embodiment, the adhesive layers 59 may be omitted. The adhesive layer 59 may include a die attach film (DAF), an adhesive or a combination thereof.

The semiconductor chips 11, 21, 31 and 41 may include chip terminals 13, 23, 33 and 43. The chip terminals 13, 23, 33 and 43 may include input/output pads, power pads and ground pads. The chip terminals 13, 23, 33 and 43 may include a conductive material such as Al, Cu, Ti, TiN, Ta, TaN, Co, Ag, Pt, Au, Sn or a combination thereof. The semiconductor chips 11, 21, 31 and 41 may include internal circuits configured by various active/passive elements which are electrically connected to the chip terminals 13, 23, 33 and 43, but detailed description thereof will be omitted for the sake of simplicity in explanation.

Each of the semiconductor chips 11, 21, 31 and 41 may include a memory such as a volatile memory, a nonvolatile memory or a combination thereof. Each of the semiconductor chips 11, 21, 31 and 41 may include a dynamic random access memory (DRAM), a static random access memory (SRAM), a flash memory, a magnetoresistive random access memory (MRAM), a phase-change random access memory (PRAM), a ferroelectric random access memory (FRAM), a resistive random access memory (RRAM), or a combination thereof. In an embodiment, at least one of the semiconductor chips 11, 21, 31 and 41 may be a logic chip such as a controller.

Fourth connecting interconnections 64 may be formed on the fourth chip terminals 43.

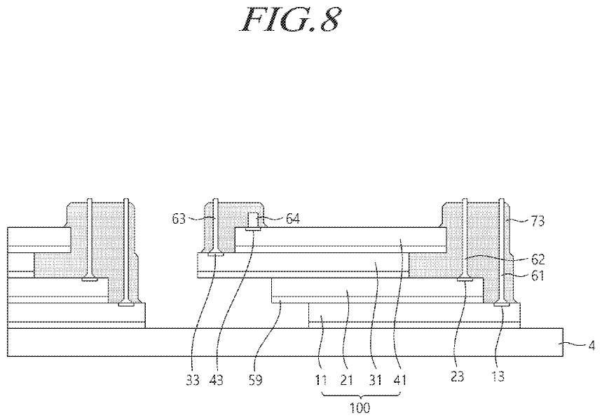

Referring to FIG. 7, first to third connecting interconnections 61, 62 and 63 may be formed on the first to third chip terminals 13, 23 and 33.

In an embodiment, each of the first connecting interconnections 61, the second connecting interconnections 62 and the third connecting interconnections 63 may include a vertical wire such as a bonding wire. Each of the fourth connecting interconnections 64 may include a copper pillar bump. In an embodiment, each of the fourth connecting interconnections 64 may include a vertical wire such as a bonding wire formed in a similar method to each of the first connecting interconnections 61, the second connecting interconnections 62 and the third connecting interconnections 63. The connecting interconnections 61, 62, 63 and 64 may include Au, Ag, Cu, Al, Sn or a combination thereof.

Referring to FIG. 8, a first encapsulation layer 73 which is adjacent to the connecting interconnections 61, 62, 63 and 64 may be formed. The first encapsulation layer 73 may be formed along the edge of the chip stack 100. In an embodiment, the first encapsulation layer 73 may be formed along at least a portion of the edge of the chip stack 100. For example, the first encapsulation layer 73 may be formed along the edges of the second to fourth semiconductor chips 21, 31, and 41 of the chip stack 100. The first encapsulation layer 73 may be formed to surround at least a portion of the side surfaces of each of the connecting interconnections 61, 62, 63 and 64.

In an embodiment, a heat treatment process for hardening the first encapsulation layer 73 may be performed. For example, the heat treatment process for hardening the first encapsulation layer 73 may be performed at a temperature range of 50° C. to 200° C. The heat treatment process for hardening the first encapsulation layer 73 may be omitted.

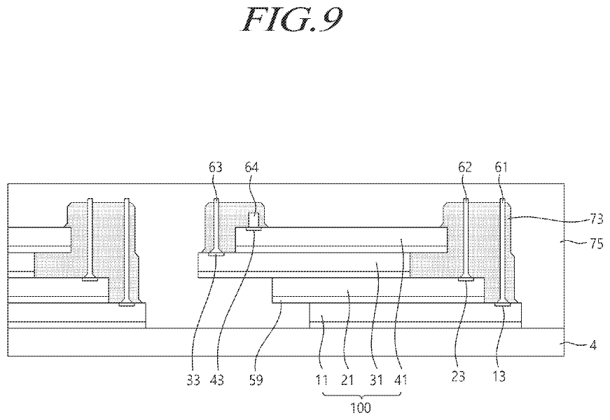

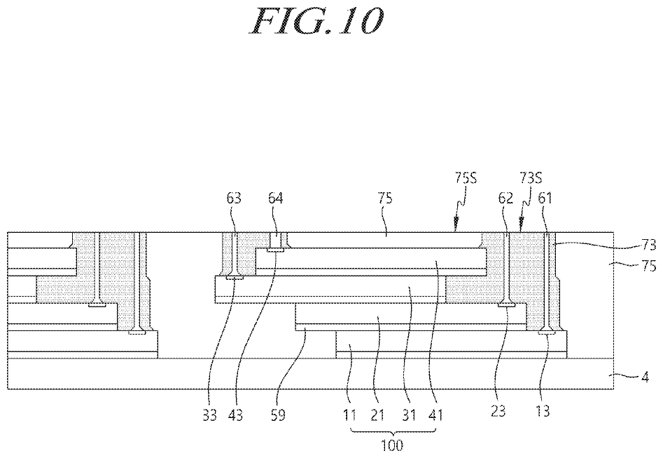

Referring to FIG. 9, a second encapsulation layer 75 which covers the chip stack 100 may be formed on the carrier 4. In an embodiment, the second encapsulation layer 75 may be formed to completely cover the side surface and the top surface of the chip stack 100, completely cover the side surface and the top surface of the first encapsulation layer 73 and completely cover the connecting interconnections 61, 62, 63 and 64. The second encapsulation layer 75 may be formed using a molding process.

The first encapsulation layer 73 may include first resin and first fillers. The second encapsulation layer 75 may include second resin and second fillers. In an embodiment, the first resin and first fillers may be different than the second resin and the second fillers. In an embodiment, the first resin and first fillers may be the same as the second resin and the second fillers. In an embodiment, the average size of the first fillers may be smaller than the average size of the second fillers. In an embodiment, the first fillers of the first encapsulation layer 73 may have a size equal to or smaller than 3 micrometers. In an embodiment, the first fillers of the first encapsulation layer 73 may have a size of 0.1 micrometer to 3 micrometers. In an embodiment, the second fillers of the second encapsulation layer 75 may have a size equal to or smaller than 30 micrometers. In an embodiment, the second fillers of the second encapsulation layer 75 may have a size of 0.1 micrometer to 30 micrometers. In an embodiment, the average size of the first fillers of the first encapsulation layer 73 may be 1 micrometer to 2 micrometers. In an embodiment, the average size of the second fillers of the second encapsulation layer 75 may be 10 micrometers to 20 micrometers.

In an embodiment, the volume ratio of the first fillers in the first encapsulation layer 73 may be smaller than the volume ratio of the second fillers in the second encapsulation layer 75. In an embodiment, the volume ratio of the first fillers in the first encapsulation layer 73 may be 30% to 60%. In an embodiment, the volume ratio of the second fillers in the second encapsulation layer 75 may be 70% to 90%. In an embodiment, the volume ratio of the first fillers in the first encapsulation layer 73 may be about 50%, and the volume ratio of the second fillers in the second encapsulation layer 75 may be about 80%.

The first encapsulation layer 73 may include a wire coating material, an underfill, a die attach film (DAF), a film over wire (FOW), an epoxy molding compound or a combination thereof. The second encapsulation layer 75 may include an epoxy molding compound. In an embodiment, the first encapsulation layer 73 may include a wire coating material.

Referring to FIG. 10, by removing the upper regions of the second encapsulation layer 75, the first encapsulation layer 73 and the connecting interconnections 61, 62, 63 and 64, the top surfaces of the second encapsulation layer 75, the first encapsulation layer 73 and the connecting interconnections 61, 62, 63 and 64 may be exposed on substantially the same plane. Removing the upper regions of the second encapsulation layer 75, the first encapsulation layer 73 and the connecting interconnections 61, 62, 63 and 64 may include a grinding process.

While a process of removing the upper regions of the second encapsulation layer 75, the first encapsulation layer 73 and the connecting interconnections 61, 62, 63 and 64 is performed, as illustrated in FIGS. 2 and 3, a first surface 73S of the first encapsulation layer 73 and a second surface 75S of the second encapsulation layer 75 may be formed to have different surface roughnesses. The first surface 73S may have a first roughness, and the second surface 75S may have a second roughness. Due to the material composition of each of the second encapsulation layer 75 and the first encapsulation layer 73, the first roughness may be smaller than the second roughness.

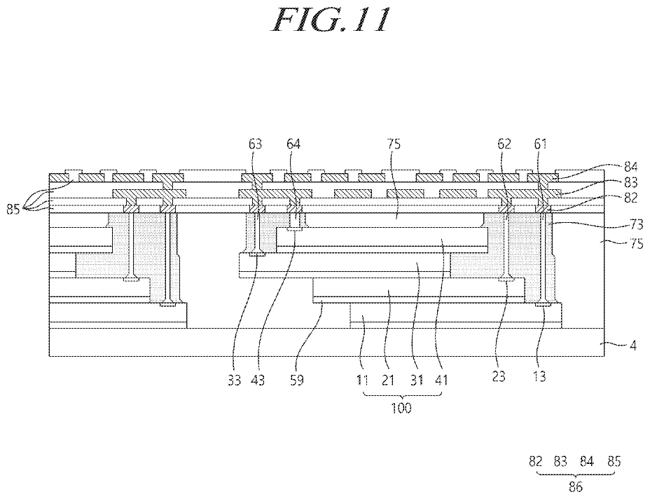

Referring to FIG. 11, landing pads 82 may be formed on the connecting interconnections 61, 62, 63 and 64, the first encapsulation layer 73 and the second encapsulation layer 75. Internal interconnections 83 and top pads 84 may be formed on the landing pads 82. In an embodiment, an insulating layer 85 which at least partially covers the landing pads 82, the internal interconnections 83 and the top pads 84 may be formed. In an embodiment an insulating layer 85 which surrounds the landing pads 82, the internal interconnections 83 and the top pads 84 may be formed. As illustrated in FIGS. 2 and 3, the landing pad 82 may include a barrier layer 82B, a seed layer 82S and a conductive layer 82C. The barrier layer 82B may include Ti, TiN, Ta, TaN or a combination thereof. The seed layer 82S may include a Cu layer which is formed using a physical vapor deposition (PVD) method. The conductive layer 82C may include a Cu layer which is formed using an electroplating method.

Referring to FIG. 1 again, by forming external connection terminals 93 on the top pads 84 and dividing the second encapsulation layer 75 using a singulation process, a semiconductor package may be formed. The carrier 4 may be removed. The external connection terminal 93 may include a solder ball, a conductive bump, a conductive finger, a conductive tab, a conductive pin or a combination thereof.

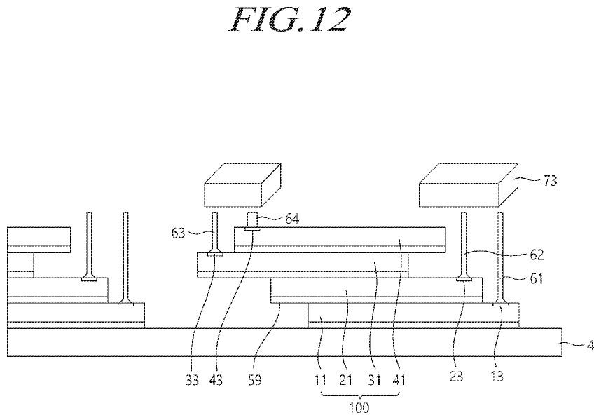

FIGS. 12 to 14 are cross-sectional views for explaining a method for forming a semiconductor package based on an embodiment of the disclosed technology.

Referring to FIG. 12, the first encapsulation layer 73 may be provided in a pre-processed shape such as a die attach film (DAF) and a film over wire (FOW). In order to maintain the pre-processed shape, the first encapsulation layer 73 may be provided on a dedicated carrier such as a dummy chip. However, detailed description thereof will be omitted for the sake of simplicity in explanation. The first encapsulation layer 73 may be aligned on the connecting interconnections 61, 62, 63 and 64.

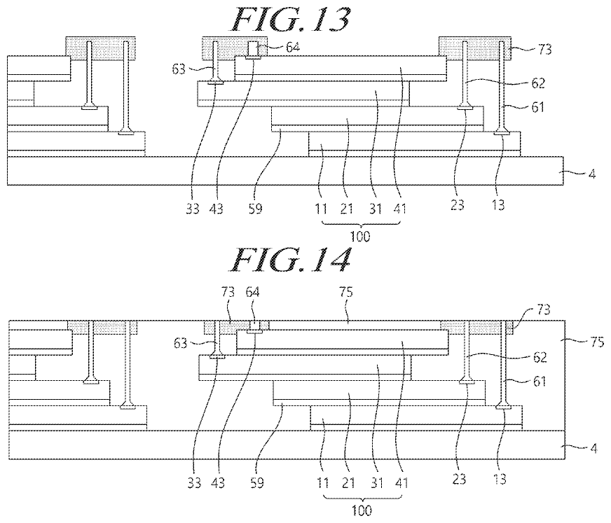

Referring to FIG. 13, the first encapsulation layer 73 which is adjacent to the connecting interconnections 61, 62, 63 and 64 may be formed on the chip stack 100. The first encapsulation layer 73 may at least cover partial regions of the chip stack 100 adjacent to the connecting interconnections 61, 62, 63 and 64. Each of the connecting interconnections 61, 62, 63 and 64 may at least partially penetrate into the first encapsulation layer 73. Each of the connecting interconnections 61, 62, 63 and 64 may pass through the first encapsulation layer 73. In an embodiment, the uppermost end of the first encapsulation layer 73 may be formed at a level higher than the top surface of an uppermost semiconductor chip (e.g., the fourth semiconductor chip 41). The lowermost end of the first encapsulation layer 73 may be formed at a level lower than the top surface of the fourth semiconductor chip 41. The lowermost end of the first encapsulation layer 73 may be formed at a level higher than the bottom surface of the uppermost semiconductor chip (e.g., the fourth semiconductor chip 41).

Referring to FIG. 14, the second encapsulation layer 75 may be formed in a method similar to that described above with reference to FIGS. 9 and 10. The top surfaces of the second encapsulation layer 75, the first encapsulation layer 73 and the connecting interconnections 61, 62, 63 and 64 may be exposed on substantially the same plane.

Although various embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A semiconductor package comprising:
a semiconductor chip;
a bonding wire connected to the semiconductor chip;
a first encapsulation layer surrounding the bonding wire; and
a second encapsulation layer surrounding the first encapsulation layer, a surface roughness of the first encapsulation layer being less than that of the second encapsulation layer; and
a landing pad contacting the bonding wire.

2. The semiconductor package according to claim 1,
wherein the first encapsulation layer includes a first surface which has a first roughness, and
wherein the second encapsulation layer includes a second surface which has a second roughness, the first roughness being less than the second roughness.

3. The semiconductor package according to claim 2,
wherein the landing pad extends onto the first surface, and
wherein the landing pad directly contacts the first surface.

4. The semiconductor package according to claim 2, wherein the first surface, the second surface and one surface of the bonding wire form substantially the same plane.

5. The semiconductor package according to claim 2, further comprising:
an insulating layer on the first surface and the second surface,
wherein the landing pad is disposed in the insulating layer, and
wherein one surface of the insulating layer directly contacts the first surface and the second surface.

6. The semiconductor package according to claim 1,
wherein the first encapsulation layer includes first resin and first fillers,
wherein the second encapsulation layer includes second resin and second fillers, and
wherein an average size of the first fillers is less than that of the second fillers.

7. The semiconductor package according to claim 1,
wherein the first encapsulation layer includes first resin and first fillers,
wherein the second encapsulation layer includes second resin and second fillers, and
wherein a volume ratio of the first fillers in the first encapsulation layer is less than a volume ratio of the second fillers in the second encapsulation layer.

8. The semiconductor package according to claim 1, wherein the first encapsulation layer includes a wire coating material, an underfill, a die attach film (DAF), a film over wire (FOW), an epoxy molding compound or a combination thereof.

9. The semiconductor package according to claim 1, wherein the second encapsulation layer includes an epoxy molding compound.

10. The semiconductor package according to claim 1,
wherein the semiconductor chip includes a chip terminal, and
wherein the bonding wire overlaps the chip terminal.

11. The semiconductor package according to claim 10, wherein the landing pad overlaps the bonding wire.

12. A semiconductor package comprising:
a semiconductor chip;
a connecting interconnection connected to the semiconductor chip;
a first encapsulation layer surrounding the connecting interconnection;
a second encapsulation layer surrounding the first encapsulation layer, a surface roughness of the first encapsulation layer being less than that of the second encapsulation layer; and
a landing pad contacting the connecting interconnection,
wherein the connecting interconnection includes a vertical wire, a conductive pillar, a conductive bump or a combination thereof.

13. A semiconductor package comprising:
a chip stack including a plurality of semiconductor chips which are stacked to be offset from each other;
a copper pillar bump connected to one semiconductor chip disposed at an uppermost layer among the plurality of semiconductor chips;
a plurality of vertical wires connected to remaining semiconductor chips except the one semiconductor chip disposed at the uppermost layer among the plurality of semiconductor chips;
a first encapsulation layer adjacent to the plurality of vertical wires and the copper pillar bump;
a second encapsulation layer disposed on a side surface of the first encapsulation layer, a surface roughness of the first encapsulation layer being less than that of the second encapsulation layer; and
a plurality of landing pads on the plurality of vertical wires and the copper pillar bump.

14. The semiconductor package according to claim 13,
wherein the first encapsulation layer includes a first surface which has a first roughness,
wherein the second encapsulation layer includes a second surface which has a second roughness, the first roughness being less than the second roughness, and
wherein the semiconductor package further comprises an insulating layer directly contacting the first surface and the second surface.

15. The semiconductor package according to claim 13, wherein a lowermost end of the first encapsulation layer is provided at a level lower than a top surface of one semiconductor chip disposed at an uppermost end among the plurality of semiconductor chips.

16. The semiconductor package according to claim 15, wherein a lowermost end of the first encapsulation layer is provided at a level higher than a top surface of one semiconductor chip disposed at a lowermost end among the plurality of semiconductor chips.

17. The semiconductor package according to claim 15, wherein a lowermost end of the first encapsulation layer is provided at a level higher than a bottom surface of one semiconductor chip disposed at an uppermost end among the plurality of semiconductor chips.

18. The semiconductor package according to claim 13, wherein the second encapsulation layer surrounds a side surface of the first encapsulation layer.

19. The semiconductor package according to claim 13, wherein the plurality of semiconductor chips comprise:
a first semiconductor chip;
a second semiconductor chip stacked on the first semiconductor chip to be offset in a first direction;
a third semiconductor chip stacked on the second semiconductor chip to be offset in the first direction; and
a fourth semiconductor chip stacked on the third semiconductor chip to be offset in a second direction different from the first direction.
